(19) United States
(12) Patent Application Publication
(10) Pub. No.: US 2013/0285526 A1
(43) Pub. Date: Oct. 31, 2013

(54) FOLDING DEVICE

(71) Applicants: HONG FU JIN PRECISION INDUSTRY (ShenZhen) CO., LTD., (US); HON HAI PRECISION INDUSTRY CO., LTD., New Taipei (TW)

(72) Inventors: Ting-Ting ZHAO, Shenzhen (CN); He-Li WANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/726,663

(22) Filed: Dec. 26, 2012

(30) Foreign Application Priority Data
Apr. 27, 2012 (CN) 201220185033.4

(51) Int. Cl. H05K 5/02

(52) U.S. Cl. CPC H05K 5/0226
USPC 312/327

(57) ABSTRACT

A folding device includes a housing, an inner space, an inclined bottom side, a cover, and a holding assembly. The housing has an upper side. The inner space is under the upper side. The inclined bottom side is concaved from the upper side into the inner space to form a receiving recess. A part of the inner space is occupied by the receiving recess. The cover is pivotable about the housing, such that the cover is capable of folding down on the housing. The holding assembly includes a first holding member fixed on the cover, and a second holding member fixed on housing.

### BACKGROUND

1. Technical Field

The present disclosure relates to folding devices, and particularly to a folding electronic device.

2. Description of Related Art

Folding devices, such as DVD players, include a housing, a disc cover pivoted on the housing, a hook assembly for securing the disc cover and the housing together. The housing includes an inner space. One side of the housing facing the disc cover is concaved into the inner space to define a receiving recess with the same depth for receiving the cover, such that the receiving recess occupies a part space of the inner space. The hook assembly includes a holding member and a hook. The hook is positioned on the disc cover, the holding member is positioned on the housing and adjacent one side of the receiving recess. The holding member grasps the hook to fasten the disc cover and the housing. The disc cover can be pressed to move to force the holding member to disengage from the hook, such that the disc cover can be open. Therefore, the receiving recess is deep enough to allow the disc cover to move. As a result, the inner space of the housing will become smaller.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a perspective view of a folding device.

FIG. 2 is an exploded view of the folding device in FIG. 1.

FIG. 3 is a cross-section view of the folding device in FIG. 1 when the folding device is closed.

### DETAILED DESCRIPTION

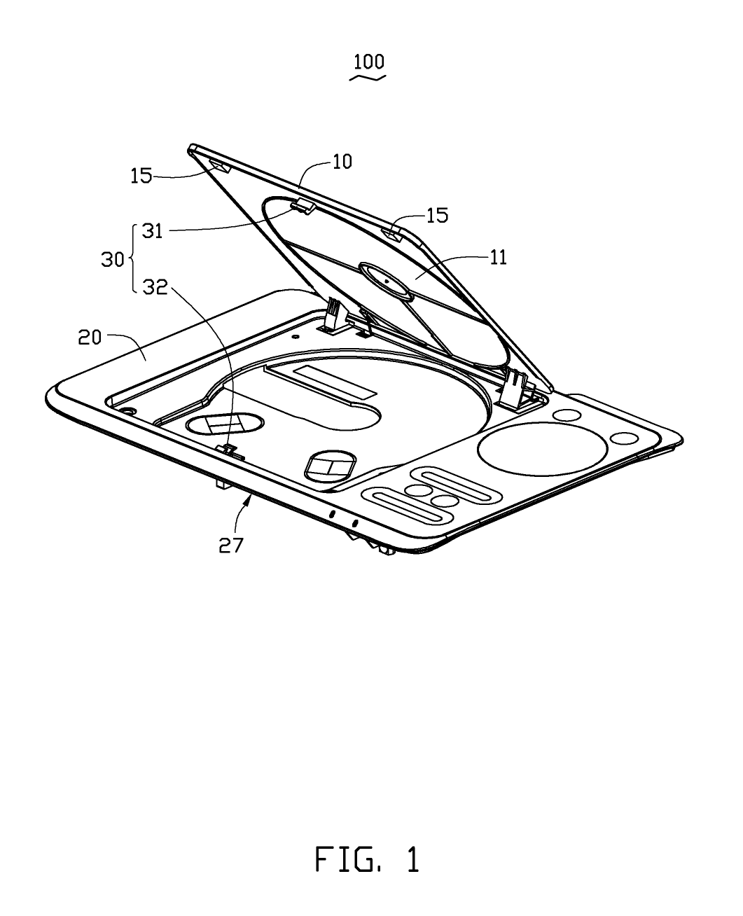

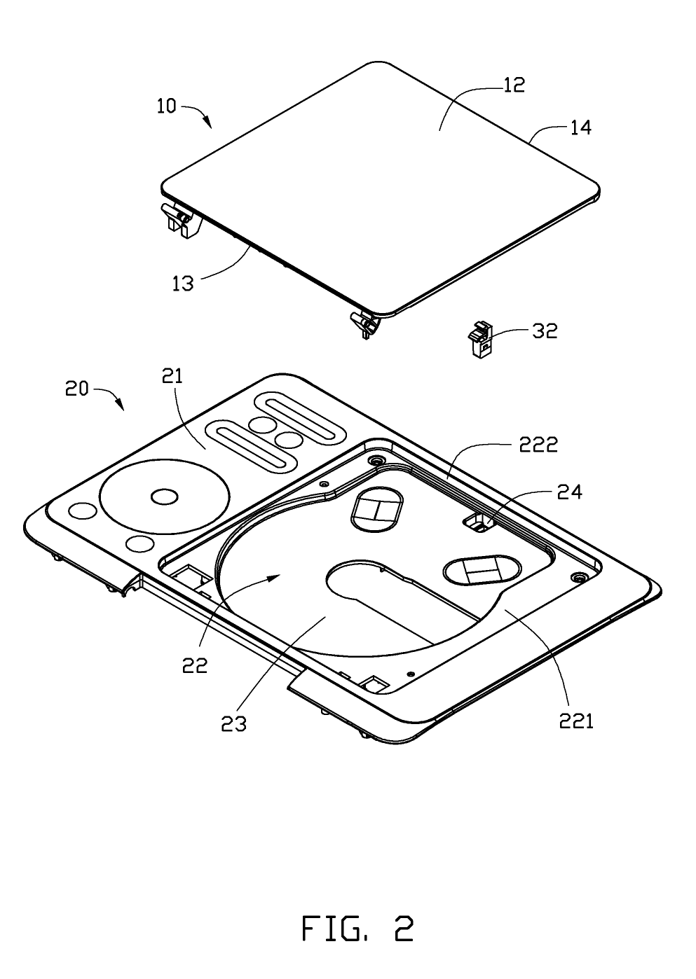

FIGS. 1 and 2 show a folding device 100 in accordance with an embodiment. The folding device 100 includes a cover 10, a housing 20, and a holding assembly 30. The cover 10 is pivoted on the housing 20, and the cover 20 is capable of being folded down to the housing 30. The holding assembly 30 is capable of holding the cover 10 and the housing 20 together when the cover 10 is folded. In this embodiment, the folding device 100 is a portable DVD player.

The cover 10 is substantially square. The cover 10 includes a top surface 12 facing the housing 20, a bottom surface 11 opposite to the top surface 12, a first side 13, and a second side 14 opposite to the first side 13. The first side 13 is hinged to the housing 20. Two cushions 15 are fixed on the bottom surface 11 symmetrically and adjacent to the second side 14. The cushions 15 are adjacent to the corner of the bottom surface 11.

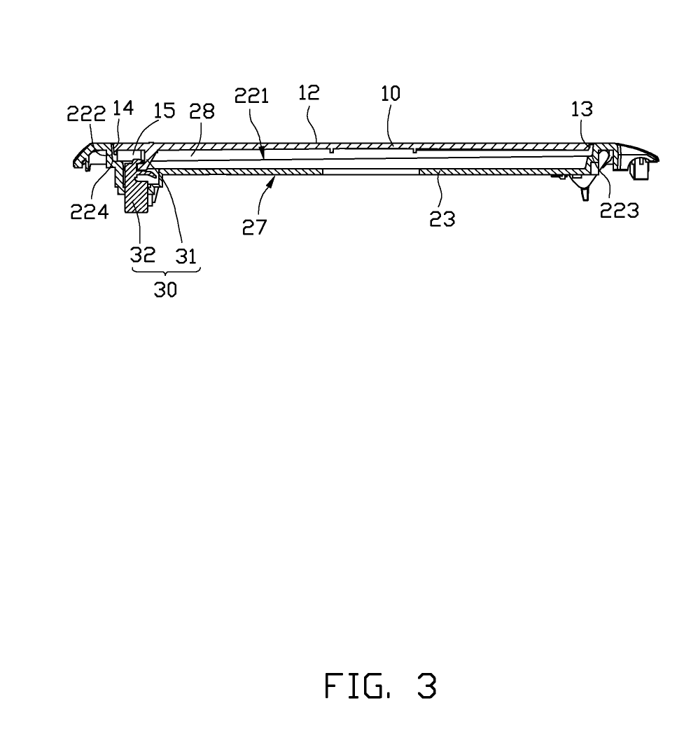

FIG. 3 shows that the housing 20 defines an inner space 27 under an upper side 21. A receiving recess 22 is defined in the upper side 21 of the housing 20 and faces to the cover 10. The receiving recess 22 receives the cover 10. The bottom surface 11 is coplanar with the upper surface (not labeled) of the upper side 21. The receiving recess 22 includes an inclined bottom side 221, a sidewall 222 surrounding the bottom side 221. The included bottom side 221 is concaved from the upper side 21 into the inner space 27 such that a part of the inner space 27 is occupied by the receiving recess 22. The bottom side 221 includes a first edge 223 corresponding to the first side 13, and a second edge 223 corresponding to the second side 14. The bottom side 221 gradually declines from the second edge 224 to the first edge 223. The depth of the receiving recess 22 viewed from the second edge 224 is lager than the depth of the receiving recess 22 viewed from the first edge 223. The bottom side 221 is concaved to form a tray 23 in the middle. A through hole 24 is defined in the bottom side 221 and adjacent to the second edge 224.

The holding assembly 30 includes a first holding member 31, and a second holding member 32. The first holding member 31 protrudes from the bottom surface 14 and the first holding member 31 is adjacent to the middle of the second side 14. The first holding member 31 and the two cushions 15 are arranged in a line. The second holding member 32 is secured to the housing 20 and is received in the through hole 24. When the cover 10 is opened, the cover 10 can be folded down on the housing 20. The cover 10 is pressed from the opened position until the first holding member 31 engages with second holding member 32, such that the cover 10 is received in the receiving recess 22 and secured to the housing 20. At the same time, there is a space 28 formed between the bottom side 221 of the receiving recess 22 and the cover 10, the cushions 15 contact the bottom side 22, such that the cover 10 is supported by cushions 15. In order to open the cover 12, the cover 10 is pressed from the position which corresponds to the first holding member 31, the first holding member 31 will disengage the second holding member 32, such that the cover 10 is capable of rotating open.

Even though relevant information and the advantages of the present embodiments have been set forth in the foregoing description, together with details of the functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. A folding device, comprising:
a housing defining a receiving recess, the receiving recess comprising a bottom side with a first edge and a second edge opposite to the first edge;
a cover comprising a first side corresponding to the first edge, and a second side opposite to the first side and corresponding to the second edge, the first side being pivotable connected to the housing, such that the cover is capable of folding down to the housing; and
a holding assembly comprising a first holding member fixed on the cover and adjacent to the second side, and a second holding member fixed on the housing and adjacent to the second edge, the first holding member being engaged with the second housing to secured the cover to the housing;
wherein the receiving recess receives the cover when the cover is secured to the housing, a depth of the receiving recess viewed from the second edge is larger than a depth of the receiving recess viewed from the first edge, such that the receiving recess adjacent to the second edge provides a space to enable the second side of the cover to move down when disengaging the first holding member from the second holding member.

2. The folding device of claim 1, wherein the bottom side is gradually declines from the first edge to the second edge.

3. The folding device of claim 1, further comprising two cushions symmetrically fixed on the cover to contact the housing to support the cover when the cover is secured to the housing.

4. The folding device of claim 3, wherein the cushions and the first holding member are arranged in a line.

5. A folding device, comprising
a housing having an upper side;
an inner space under the upper side;
an inclined bottom side concaved from the upper side into the inner space to form a receiving recess, such that a part of the inner space is occupied by the receiving recess;
a cover being pivoted about the housing, such that the cover being capable of folding down on the housing; and
a holding assembly comprising a first holding member fixed on cover, and a second holding member fixed on the housing, the first holding member being engaged with the second housing to secured the cover to the housing;
wherein the cover is received in the receiving recess when the cover is secured to the housing, the inclined plane enables the receiving recess to provide a space for disengaging the first holding member from the second holding member when the cover is secured to the housing.

6. The folding device of claim 5, wherein the bottom side comprising a first edge and a second edge opposite to the first edge, the bottom side gradually declines from the first edge to the second edge.

7. The folding device of claim 5, further comprising two cushions symmetrically fixed on the cover to contact the housing to support the cover when the cover is secured to the housing.

8. The folding device of claim 7, wherein the cushions and the first holding member are arranged in a line.
